(19) United States
(12) Patent Application Publication
(10) Pub. No.: US 2009/0242229 A1
(43) Pub. Date: Oct. 1, 2009

(54) LIGHT-EMITTING DEVICE SEALING STRUCTURE AND METHOD FOR MANUFACTURING THE SAME

(75) Inventor: Keiko Sakai, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/413,704

(22) Filed: Mar. 30, 2009

(30) Foreign Application Priority Data
Mar. 31, 2008 (JP) 2008-094083

(51) Int. Cl. H05K 5/06; H01J 9/00

(52) U.S. Cl. 174/50.51; 445/58

(57) ABSTRACT

There is provided a light-emitting device sealing structure ensuring a moisture-proof property appropriately and being excellent in easiness of processing, and a method for manufacturing the same. A light-emitting device sealing structure, includes: a light-emitting device including, a front surface having an output region from which light is output and a peripheral portion provided in a surrounding area thereof, a back surface opposite to the front surface, and a peripheral side surface between the front surface and the back surface; and a sealing layer covering the light-emitting device from the approximately entire back surface through the entire peripheral side surface to at least the peripheral portion of the front surface of the light-emitting device.

### CROSS-REFERENCE TO RELATED APPLICATIONS

This application is based upon and claims the benefit of priority from the prior Japanese Patent Application No. 2008-094083, filed on Mar. 31, 2008; the entire contents of which are incorporated herein by reference.

### BACKGROUND OF THE INVENTION

This invention relates to a light-emitting device sealing structure which includes a light emitting device and a sealing layer having moisture-proof property, and a method for manufacturing the same.

### BACKGROUND ART

In recent years, organic EL (Electro Luminescence) has been noticed as the light-emitting device with a thin shape and low power consumption. However, an organic EL element has a problem of being easily subjected to aging degradation and coming to generate, for example, non-light-emitting region called as “dark spot” or the like. Its cause is not clear, but the possibility of relation to moisture or oxygen has been indicated.

For this, it has been proposed that in the organic EL element in which at least a positive electrode, an organic light-emitting layer, and a negative electrode are sequentially stacked on a substrate having optical transparency, an inorganic passivation sealing film is provided on the surface of the stacked structure composed of the positive electrode and the organic light-emitting layer and the negative electrode, and a resin sealing film made of resin is provided on the inorganic passivation sealing film (JP-A 2000-223264 (Kokai), Patent document 1). Thereby, the organic EL element whose light-emitting characteristics are not degraded by moisture is provided.

### SUMMARY OF THE INVENTION

According to an aspect of the invention, there is provided a light-emitting device sealing structure, including: a light-emitting device including, a front surface having an output region from which light is output and a peripheral portion provided in a surrounding area thereof, a back surface opposite to the front surface, and a peripheral side surface between the front surface and the back surface; and a sealing layer covering the light-emitting device from the approximately entire back surface through the entire peripheral side surface to at least the peripheral portion of the front surface of the light-emitting device.

According to another aspect of the invention, there is provided a method for manufacturing a light-emitting device sealing structure, including: flowing a material of a sealing layer made of a thermoplastic material softened thermally into a mold after placing a light-emitting device having a light-emitting element and a power supply part configured to supply a power to the light-emitting element in the mold; cooling the processed body gradually to solidify the sealing layer; removing a portion of the power supply part on the sealing layer by a laser melting process; and attaching an electrode lead wire to the power supply part.

According to another aspect of the invention, there is provided a method for manufacturing a light-emitting device sealing structure, including: providing a mask material on a power supply part of a light-emitting device having a light-emitting element and the power supply part for supply a power to the light-emitting element; flowing a material of a sealing layer made of a thermoplastic material softened thermally into a mold after placing the light-emitting device provided with the mask material in the mold; cooling the processed body gradually to solidify the sealing layer; removing the mask material; and attaching an electrode lead wire to the power supply part.

According to another aspect of the invention, there is provided a method for manufacturing a light-emitting device sealing structure, including: attaching an electrode lead wire to a power supply part of a light-emitting device having a light-emitting element and the power supply part for supply a power to the light-emitting element; flowing a material of a sealing layer made of a thermoplastic material softened thermally into a mold after placing the light-emitting device in the mold; and cooling the processed body gradually to solidify the sealing layer.

### BRIEF DESCRIPTION OF THE DRAWINGS

FIGS. 1A and 1B are schematic views showing one example (specific example 1) of a light-emitting device sealing structure according to an embodiment of the invention;

FIGS. 2A and 2B are views for describing an organic EL element;

FIG. 3 is a schematic cross-sectional view showing a light-emitting device sealing structure 200 according to a comparative example contrasted with this embodiment;

FIGS. 4A and 4B are schematic cross-sectional views for showing the effect of the specific example 1;

FIG. 5 is a schematic cross-sectional view showing another example (specific example 2) of the light-emitting device sealing structure according to this embodiment;

FIGS. 6A and 6B are schematic cross-sectional views showing another example (specific example 3) of the light-emitting device sealing structure according to this embodiment;

FIG. 7 is a schematic cross-sectional view for showing the moisture-proof effect of a light-emitting device sealing structure according to the specific example 3;

FIGS. 8A and 8B are schematic cross-sectional views for showing another example (specific example 4) of a light-emitting device sealing structure 2 according to this embodiment;

FIGS. 9A, 9B and 9C are schematic cross-sectional views showing another examples (specific example 5, example 6 and example 8, respectively) of the light-emitting device sealing structure according to this embodiment;

FIGS. 10A to 10D are schematic process cross-sectional views showing one example of a method for manufacturing the light-emitting device sealing structure 2; and

FIGS. 11A to 11D are schematic process cross-sectional views showing another example of the method for manufacturing the light-emitting device sealing structure 2.

### DETAILED DESCRIPTION OF THE INVENTION

Hereinafter, embodiments of the invention will be described with reference to the drawings. In each of the drawings, the same signs are appended to the same components, and detailed description thereof will be appropriately omitted.

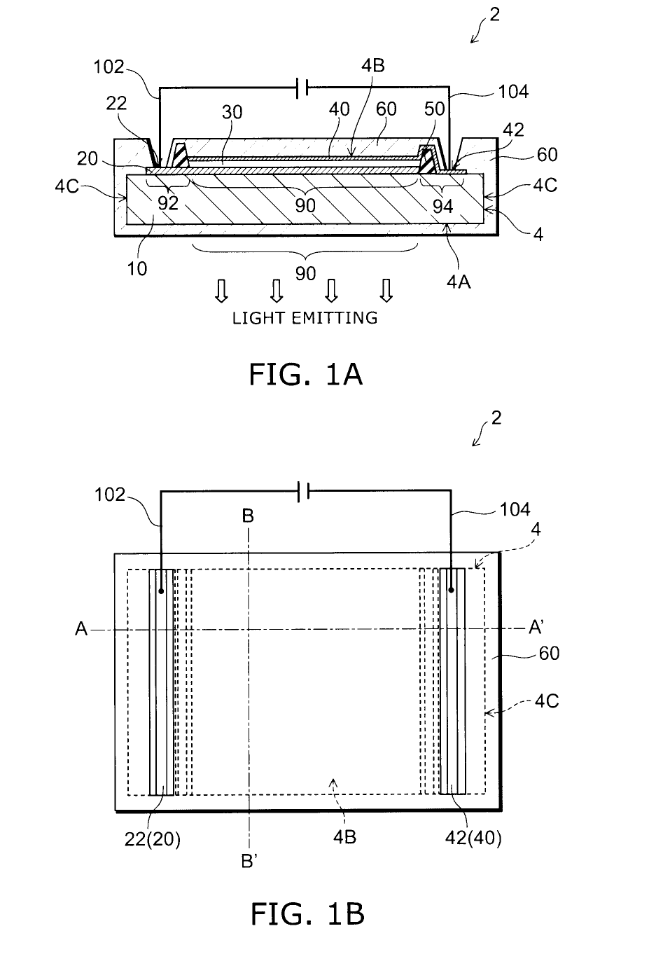

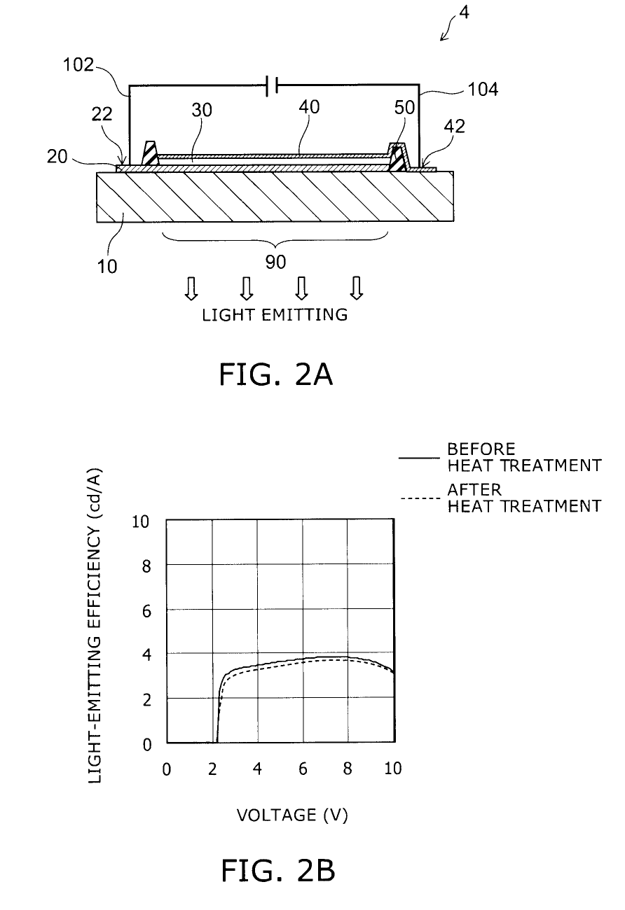

First, a light-emitting device sealing structure according to an embodiment of the invention (specific example 1) will be described with reference to FIGS. 1A to 2B.

FIGS. 1A and 1B are schematic views showing one example (specific example 1) of the light-emitting device sealing structure according to the embodiment of the invention. FIG. 1A is a schematic sectional view of the specific example 1, and FIG. 1B is a schematic plan view of the specific example 1.

FIG. 1A is a cross-sectional view taken along the line A-A′ in FIG. 1B. In this specific example, as the light-emitting device, an organic EL element will be taken up.

The light-emitting device 4 (organic EL element) used in the specific example 1 has a front surface 4A from which light is output, a back surface 4B opposite to the surface 4A, and a peripheral side surface between the surface 4A and the back surface 4B. Its structure will be described. The light-emitting device 4 includes a substrate 10 and a stacked structure in which an electrode 20, an organic EL layer 30, and an electrode 40 that are selectively provided on the substrate 10 are stacked in this order from below. In this stacked structure, the electrode 20 and the electrode 40 have portions overlapping with each other (overlapping region 90) and portions not overlapping with each other (non-overlapping regions 92, 94), in main surfaces. The organic EL layer 30 is sandwiched between the electrode 20 and the electrode 40 in the overlapping region 90. Here, “main surfaces” represents surfaces that are perpendicular to the stacked direction of the electrode 20, the organic EL layer 30, the electrode 40, and so forth.

At the boundaries between the overlapping region 90 and the non-overlapping regions 92 and 94, insulators 50 for preventing the electrode 20 and the electrode 40 from being in contact with each other are provided. The insulators 50 are provided so as to be in contact with the electrode 20, the organic EL layer 30, and the electrode 40. Moreover, the insulators 50 are provided so that the electrode 20 and the electrode 40 exist outside the main surface direction of the insulators 50 in this stacked body. In the non-overlapping region (non-overlapping region 94) in which only the electrode 40 exists, the insulator 50 is in contact with the substrate 10 and the electrode 40 is continuously in contact with the insulator 50 and the substrate 10, so that void is not generated between the components.

The electrode 20 has a power supply part 22 (power supply pad) for feeding to the light-emitting element (the organic EL layer in the specific example 1) in the light-emitting device 4 outside the main surface direction of the insulators 50, in the non-overlapping region 92. Similarly, the electrode 40 has a power supply part 42 (power supply pad) for feeding to the light-emitting device 4 outside the main surface direction of the insulators 50, in the non-overlapping region 92.

The overlapping region 90 on the front surface 4A is a region in which the electrode 20, the organic EL layer 30, and the electrode 40 overlap, and from the overlapping region 90, light is output to a certain direction (front face direction, observer side direction). Specifically, the light is output from the organic EL layer 30 through the substrate 10 to the outside. Hereinafter, the region in which the light is output to a certain direction is occasionally referred to as “output region 90”. That is, in FIG. 1, out of the overlapping region 90, the output region 90 is the region existing in the side from which the light is output (the region existing under the organic EL layer). On the other hand, from the region on the front surface 4A including the non-overlapping regions 92 and 94 in which the organic EL layer 30 does not exist, the light is not output. This region is referred to as peripheral portion. That is, the front surface 4A of the light-emitting device 4 has the output region from which the light is output and the peripheral portion of its surrounding area.

And, the light-emitting device sealing structure 2 according to this embodiment is a structure in which the light-emitting device 4 is covered with a sealing layer 60 from the approximately entire back surface 4B through the entire peripheral side surface 4C to the peripheral portion of the front surface 4A. For example, the light-emitting device sealing structure 2 may be a structure in which the entirety of the front surface 4A, the back surface 4B and the peripheral side surface 4C of the light-emitting device 4 is covered with the sealing layer 60. Moreover, the light-emitting device sealing structure 2 may be a structure in which the light-emitting device has a “coating region” that is a region covered with the sealing layer 60 and a “non-coating region” that is a region not covered with the sealing layer 60.

In the light-emitting device sealing structure 2 shown in FIG. 1A, the approximately entire surface of the light-emitting device 4 including the output region 90 is covered with the sealing layer 60, but the portions of the power supply part 22 and the power supply part 42 are not covered with the sealing layer 60. That is, in the light-emitting device sealing structure 2 according to the specific example 1, the power supply part 22 and the power supply part 42 are non-coating regions.

Next, the organic EL element that is one example of the light-emitting device 4 will be described.

FIGS. 2A and 2B are views for describing the organic EL element. FIG. 2A is a schematic cross-sectional view of the organic EL element. The components shown in FIG. 2A are the same as described for FIGS. 1A and 1B.

Between the organic EL layer 30 and the electrode 40, alkali metal compound layer may be provided. The configuration of the stacked structure of the electrode 20, the organic EL layer 30 and the electrode 40 includes, for example, ITO (electrode 20)/αNPD/Alq3/LiF/Al (electrode 40). “ITO” is indium tin oxide, and “αNPD” is 4,4′-bis[N-(1-naphthyl)-N-phenylamino]biphenyl, “Alq3” is tris(8-hydroxyquinoline)aluminum.

FIG. 2B shows a graph showing electric characteristics before and after heat treatment of the organic EL element, the configuration of the organic EL element used in this experiment is ITO (electrode 20)/αNPD/Alq3/LiF/Al (electrode 40), and the respective film thicknesses are 150/60/60/0.7/150 nm. When the organic EL element is heat-treated on a hot plate at 110° C. for 1 hour, little change is shown in the light-emitting efficiency with respect to voltage. Therefore, it is thought that the organic EL element is used in the temperature range of at least room temperature to about 100° C.

In this specific example, the case where the organic EL layer 30 is used as the light-emitting layer has been exemplified, but the invention is not limited thereto. That is, the light-emitting device provided with a light-emitting layer composed of another structure or material instead of the organic EL layer 30 is also included in the scope of the invention.

Next, the sealing layer 60 will be described.

For the sealing layer 60, a coating material that is transparent and excellent in moisture-proof property and can be easily processed (such as thermoplastic material) can be used. Here, according to this specific example, the approximately entire surface of the light-emitting device 4 is continuously covered with the sealing layer 60, and therefore, even if the material having relatively low adhesion to the light-emitting device 4 is used, the adhesion is appropriately ensured structurally. Therefore, various thermoplastic materials can be used for the sealing layer 60.

The specific examples of such a sealing layer 60 includes thermoplastic materials having siloxane bonds and organic functional groups, such as, “organic-inorganic hybrid low-melting-point glass that is obtained by heating and reacting alkylchlorosilane and phosphorous acid and that has a composition of xR₂SiCl₂.H₃PO₃ (x=0.1 to 3) (where, R is methyl group or ethyl group)” or “organic-inorganic hybrid low-melting-point glass that is obtained by heating and reacting alkylchlorosilane and phosphorous acid and metal chloride and that has a composition of xR₂SiCl₂.2H₃PO₃.2MCl₂ (x=0.1 to 2) (where, M is bivalent metal of Sn, Zn, or Ge. R is methyl group or ethyl group)”. Hereinafter, such a material will be referred to as “thermoplastic siloxane-based inorganic-organic hybrid material”.

Conventionally, as the sealing film for ensuring moisture-proof property of the light-emitting device such as an organic EL element, inorganic films such as SiO₂, SiN and SiON or resin films such as epoxy resin, acryl resin, and silicone resin have been used. However, the former inorganic films are generally formed by dry film formation and have a problem that the vacuum apparatus used therefor is expensive and the process cost is high such as the long film formation time. On the other hand, the latter resin films have a problem that the moisture-proof property is not sufficiently ensured (it is thought that residual moisture has the influence). By contrast, the above “thermoplastic siloxane-based inorganic-organic hybrid material” is expected to be a material having both of high moisture-proof property and easiness of the film formation.

Moreover, the “thermoplastic siloxane-based inorganic-organic hybrid material” has a softening point of about 100° C., and therefore, the material has sufficiently durable temperature in the general operational environment of the organic EL element.

The film thickness of the sealing layer 60 is not particularly limited and can be appropriately selected in consideration of purpose of use or securement of appropriate brightness or the like of the light-emitting device 4. When the film thickness is set to be larger, the moisture-proof performance or the ultraviolet-shielding performance to be described later becomes higher.

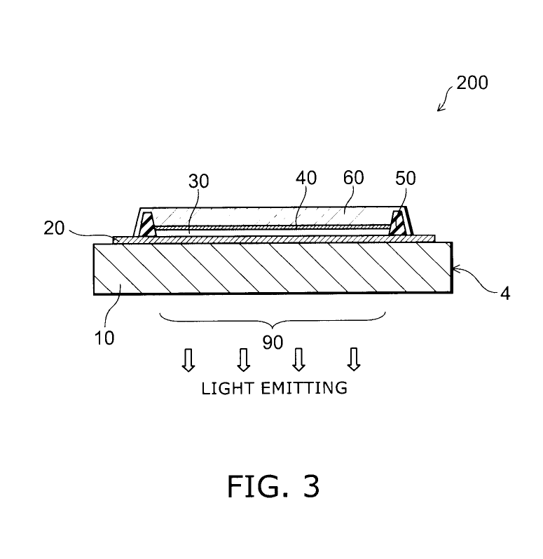

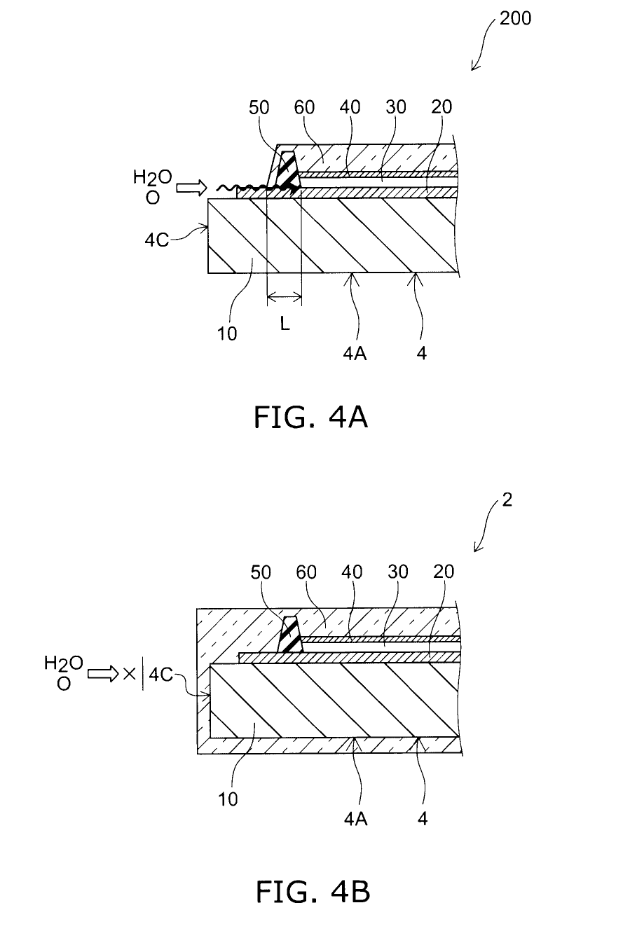

Next, the effect of this embodiment will be described with reference to FIGS. 3 to 4B.

FIG. 3 is a schematic cross-sectional view showing a light-emitting device sealing structure 200 according to a comparative example contrasted with this embodiment. FIG. 3 corresponds to a cross-sectional view taken along the line B-B′ in FIG. 1B. As shown in FIG. 3, in the comparative example, the sealing layer 60 is provided only on the back surface of the light-emitting device 4. That is, the light-emitting device sealing structure 200 according to the comparative example is different from this embodiment and does not have the structure in which the peripheral side surface and the peripheral are covered with the sealing layer 60.

FIGS. 4A and 4B are schematic cross-sectional views for showing the effect of the specific example 1. FIG. 4A is a schematic cross-sectional view showing an end portion of the light-emitting device sealing structure 200 according to the comparative example, and FIG. 4B is a schematic cross-sectional view showing an end portion of the light-emitting device sealing structure 2 according to the specific example 1.

As shown in FIG. 4A, in the light-emitting device sealing structure 200 according to the comparative example, there is possibility that water or oxygen gets into the boundary between the sealing layer 60 and the electrode 20 in the end portion. Moreover, the water or oxygen getting thereinto reaches the organic EL layer 30 through a relatively short pathway (pathway length L). Thereby, it is feared that the light-emitting device 4 is degraded.

By contrast, as shown in FIG. 4B, in the light-emitting device sealing structure 2 according to the specific example 1, the boundary between the sealing layer 60 and other components does not exist in the end portion. Therefore, the possibility that water or oxygen gets into the light-emitting device sealing structure 2 is reduced. That is, the possibility that the light-emitting device 4 is degraded is reduced.

Furthermore, the sealing layer 60 may be provided with a function of shielding an ultraviolet ray. That is, when the ultraviolet ray is emitted from the organic EL (or the light-emitting layer composed of a structure and a material except therefor), the sealing layer 60 can be provided with a function of shielding the leakage of the ultraviolet ray to the outside. For this, it is sufficient that the sealing layer 60 has a predetermined absorptance or reflectance with respect to the ultraviolet ray.

Also, conversely, ultraviolet ray from the outside can be prevented from getting into the inside of the light-emitting device 4. For example, the ultraviolet ray included in solar light or the like can get into the inside of the light-emitting device 4 and the light-emitting device 4 can be degraded. In such a case, by providing the sealing layer 60 with the ultraviolet shielding function, the degradation of the light-emitting device 4 by the ultraviolet ray can be prevented.

Moreover, because the light-emitting device 4 is covered with the sealing layer 60, adhesion between the light-emitting device 4 and sealing layer 60 can be appropriately ensured. From this viewpoint, the moisture-proof property of the light-emitting device 4 is appropriately ensured.

Furthermore, as described above, because the thermoplastic material that is excellent in easiness of processing can be used for the sealing layer 60, the sealing process becomes easy. Therefore, the relatively inexpensive light-emitting device sealing structure is provided.

As described above, according to the light-emitting device sealing structure 2 according to this embodiment (specific example 1), the moisture-proof property of the light-emitting device 4 is appropriately ensured. The easiness of processing is achieved, and the relatively inexpensive light-emitting device sealing structure is provided.

### Other Embodiments

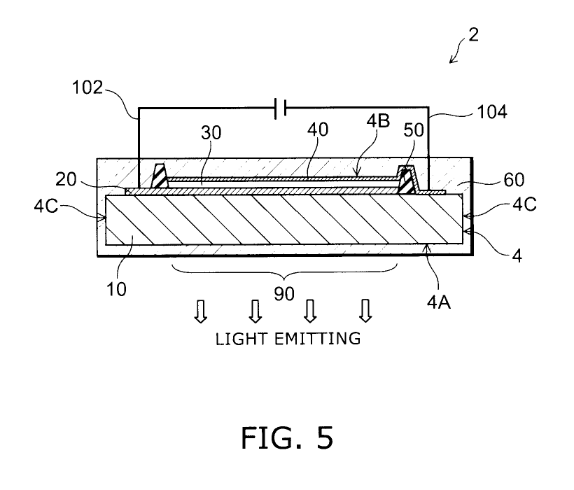

Next, other embodiments will be described with reference to FIGS. 5 to 9C.

FIG. 5 is a schematic cross-sectional view showing another example (specific example 2) of the light-emitting device sealing structure according to this embodiment. FIG. 5 corresponds to a cross-sectional view taken along the line A-A′ in FIG. 1B. As shown in FIG. 5, the light-emitting device sealing structure 2 according to the specific example 2 has basically the same structure as the light-emitting device sealing structure 2, but the entire surface of the light-emitting device 4 including portions of the power supply part 22 and the power supply part 42 is covered with the sealing layer 60. That is, the entirety of the front surface 4A and the back surface 4B and the peripheral side surface 4C is covered with the sealing layer 60. Alternatively, the structure in which the region other than the region in the vicinity of the electrode lead wires 102 and 104 attached to the light-emitting device 4 may be covered with the sealing layer 60. By such a structure, the contact region between the light-emitting device 4 and the outside (outside air) is more reduced, and therefore, the moisture-proof effect and the ultraviolet-shielding effect become more preferable.

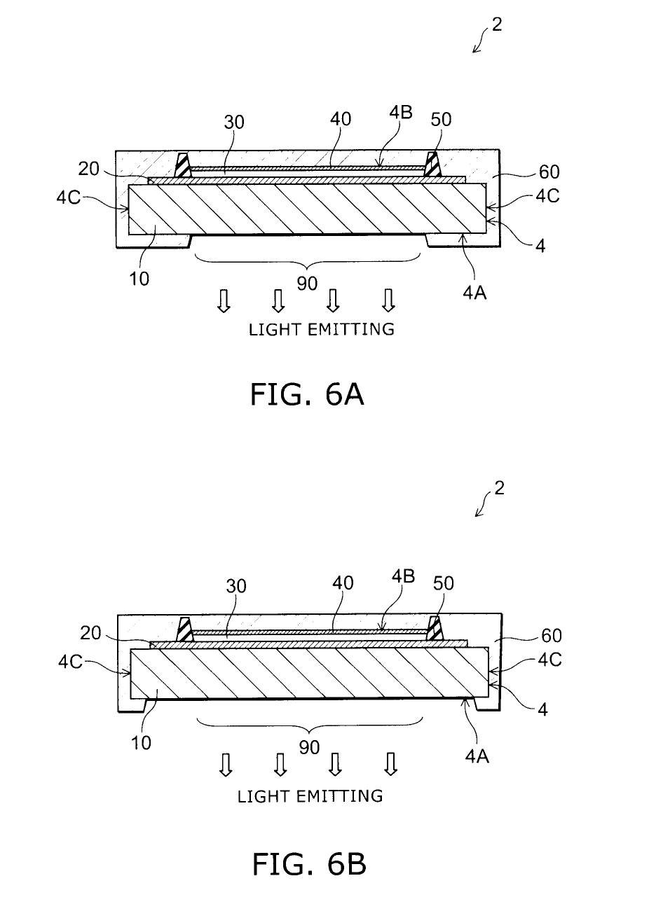

FIGS. 6A and 6B are schematic cross-sectional views showing another example (specific example 3) of the light-emitting device sealing structure according to this embodiment. FIGS. 6A and 6B correspond to cross-sectional views taken along the line B-B′ in FIG. 1B. As shown in FIG. 6A, the light-emitting device sealing structure 2 according to the specific example 3 has basically the same structure as the light-emitting device sealing structure 2 according to the specific example 1, but the portion of the output region 90 of the front surface 4A is not covered with the sealing layer 60. That is, in addition to the power supply part 22 and the power supply part 42 of the back surface 4B, the output region 90 is also non-coating region. Moreover, as shown in FIG. 6B, in the front surface 4A, as well as the output region 90, part of the peripheral portion can be the non-coating region. Even by such a structure, good moisture-proof effect can be obtained.

Moreover, in this case, when the substrate 10 has an ultraviolet-shielding function, leakage of ultraviolet to the outside or the invasion of ultraviolet from the outside can be prevented.

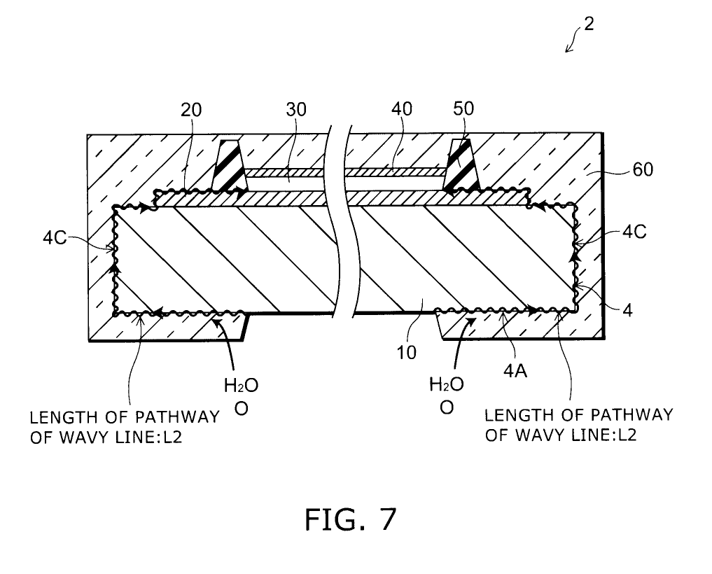

FIG. 7 is a schematic cross-sectional view for showing the moisture-proof effect of the light-emitting device sealing structure 2 according to the specific example 3. As shown in FIG. 7, in the specific example 3, there is possibility that water or oxygen intrudes from the interface between the sealing layer 60 and the substrate 10. However, in the specific example 3, the pathway length (L2) is relatively long from the intrusion port to the organic EL layer 30, and therefore, the possibility that the light-emitting device 4 is degraded is relatively low. The sealing layer 60 covers part of the front face side of the light-emitting device, and therefore, the possibility that the sealing layer 60 is delaminated from the light-emitting device 4 is low and the adhesion thereof is appropriately ensured. Moreover, if a material by which the adhesion to the light-emitting device 4 is appropriately ensured and which is difficult to be delaminated is selected as the material of the sealing layer 60, the moisture-proof property is more improved.

In this specific example, because the sealing layer 60 does not cover the output region 90, an opaque material can be used for the sealing layer 60.

Moreover, because the sealing layer 60 does not exist in the output region 90, the orientation characteristics of the light output from the organic EL layer 30 are not modified by the sealing layer 60. That is, the light is output in the front face direction without affected by the refraction index of the sealing layer 60. Therefore, the effect improving the light-emitting characteristics to the front face direction can also be obtained.

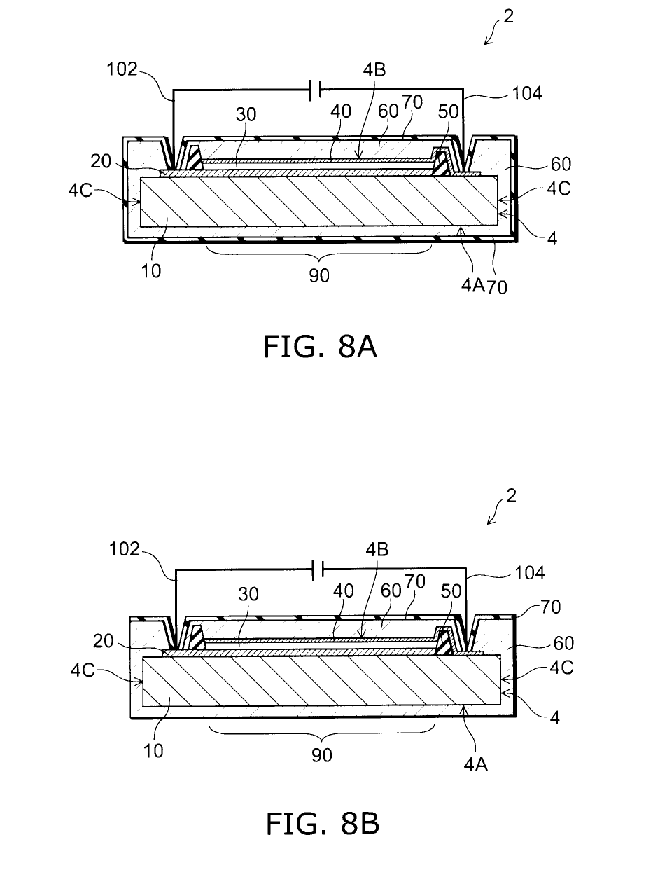

FIGS. 8A and 8B are schematic cross-sectional views showing another example (specific example 4) of the light-emitting device sealing structure according to this embodiment. As shown in FIG. 8A, the light-emitting device sealing structure 2 according to the specific example 4 has basically the same structure as the light-emitting device sealing structure 2 according to the specific example 1, but the periphery of the sealing layer 60 is covered with an inorganic layer 70 made of a material having an inorganic compound as the main component. Thereby, the moisture-proof property is further improved. Moreover, as shown in FIG. 8B, the inorganic layer 70 may be provided only over the back surface 4B.

Moreover, when ultraviolet is shielded in this specific example, it is sufficient that any one of the sealing layer 60 and the inorganic layer 70 is provided with an ultraviolet-shielding function, the range of selection of materials becomes large, and the ultraviolet-shielding structure can be more easily realized.

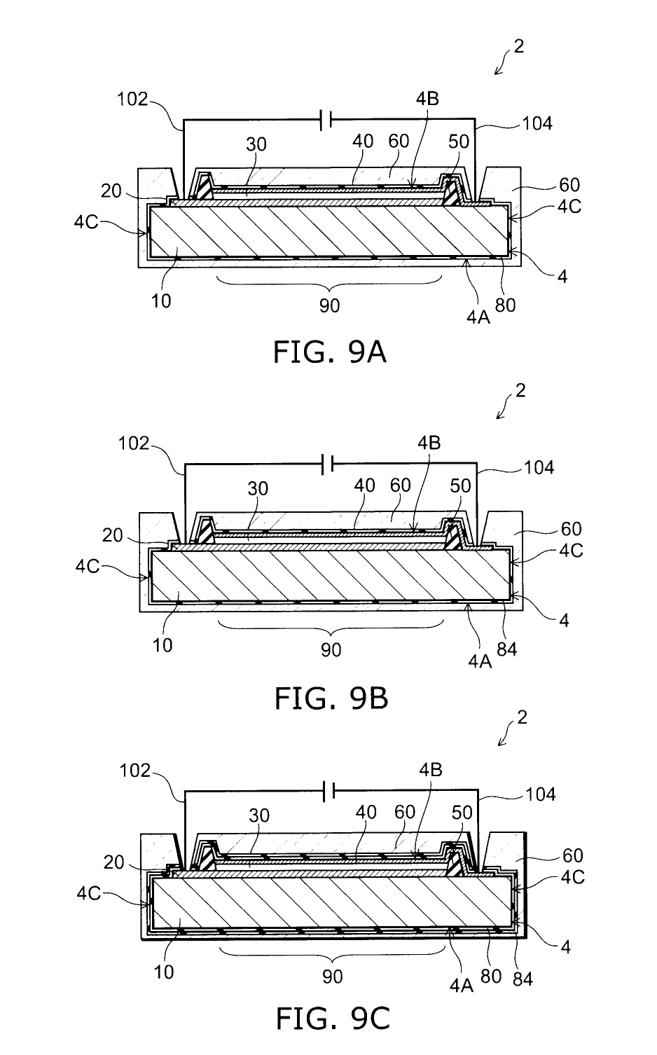

FIG. 9A is a schematic cross-sectional view showing another example (specific example 5) of the light-emitting device sealing structure according to this embodiment. As shown in FIG. 9A, the light-emitting device sealing structure 2 according to the specific example 5 has basically the same structure as the light-emitting device sealing structure 2 according to the specific example 1, but a stress-relaxing layer 80 for relaxing a stress generated between the light-emitting device 4 and the sealing layer 60 is provided between the light-emitting device 4 and the sealing layer 60. When there is difference of thermal expansion coefficients between the light-emitting device 4 (such as the organic EL element) and the sealing layer 60 (such as the above “thermoplastic siloxane-based inorganic-organic hybrid material”), a crack is occasionally caused in the sealing layer 60 by the stress generated by this difference. In this specific example, for relaxing the stress and suppressing generation of the crack, the stress-relaxing layer 80 is provided.

FIG. 9B is a schematic cross-sectional view showing another example (specific example 6) of the light-emitting device sealing structure according to this embodiment. As shown in FIG. 9B, the light-emitting device sealing structure 2 according to the specific example 6 has basically the same structure as the light-emitting device sealing structure 2 according to the specific example 1, but an adhesion layer 84 for making the light-emitting device 4 and the sealing layer 60 adhere tightly to each other is provided between the light-emitting device and the sealing layer 60. Thereby, the adhesion property between the light-emitting device 4 and the sealing layer 60 is more improved.

FIG. 9C is a schematic cross-sectional view showing another example (specific example 7) of the light-emitting device sealing structure according to this embodiment. Like the specific example 7, the stress-relaxing layer 80 and the adhesion layer 84 may be used together. The method for disposing the stress-relaxing layer 80 and the adhesion layer 84 can be appropriately selected, in consideration of the materials of the light-emitting device 4 and the sealing layer 60, and so forth. In FIG. 9C, the stress-relaxing layer 80 is provided inside (in the side of the light-emitting device), and the adhesion layer 84 is provided outside (in the side of the sealing layer 60), but reverse thereof is also possible.

Moreover, in the specific examples 5 to 7, in the case of shielding ultraviolet light, it is sufficient that any one of the stress-relaxing layer 80, the adhesion layer 84, and the sealing layer 60 to be used is provided with the ultraviolet-shielding function, and thereby the range of selection of the materials becomes large and the ultraviolet-shielding structure can be more easily realized.

Method for manufacturing the light-emitting device sealing structure 2

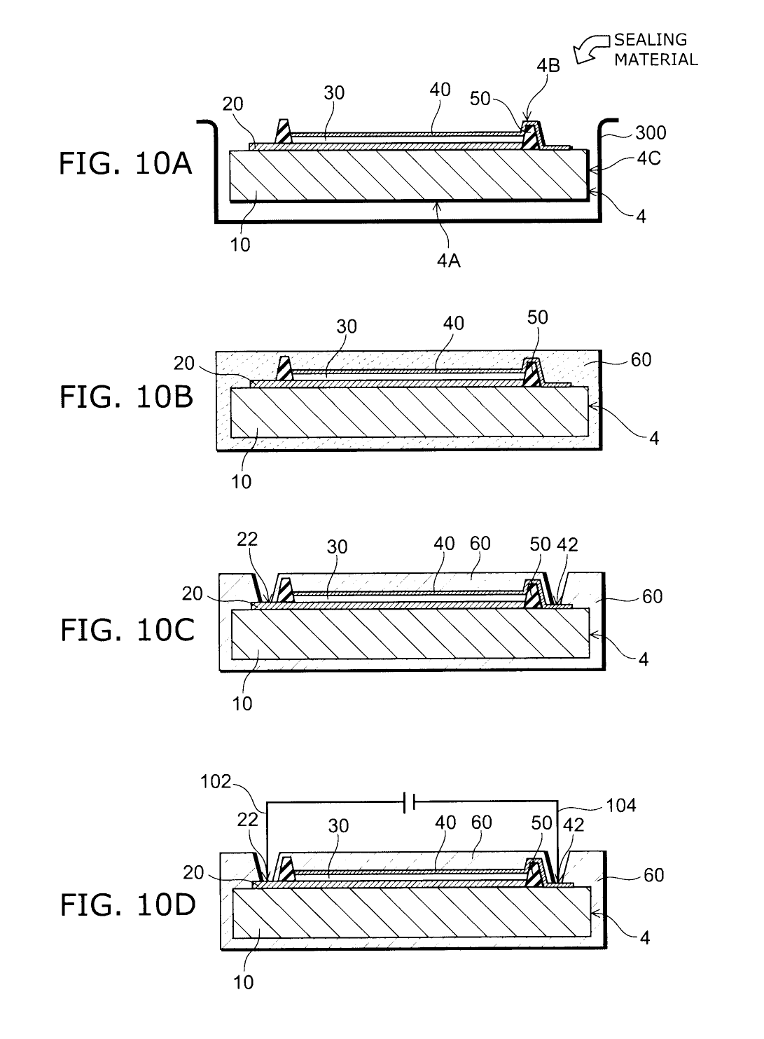

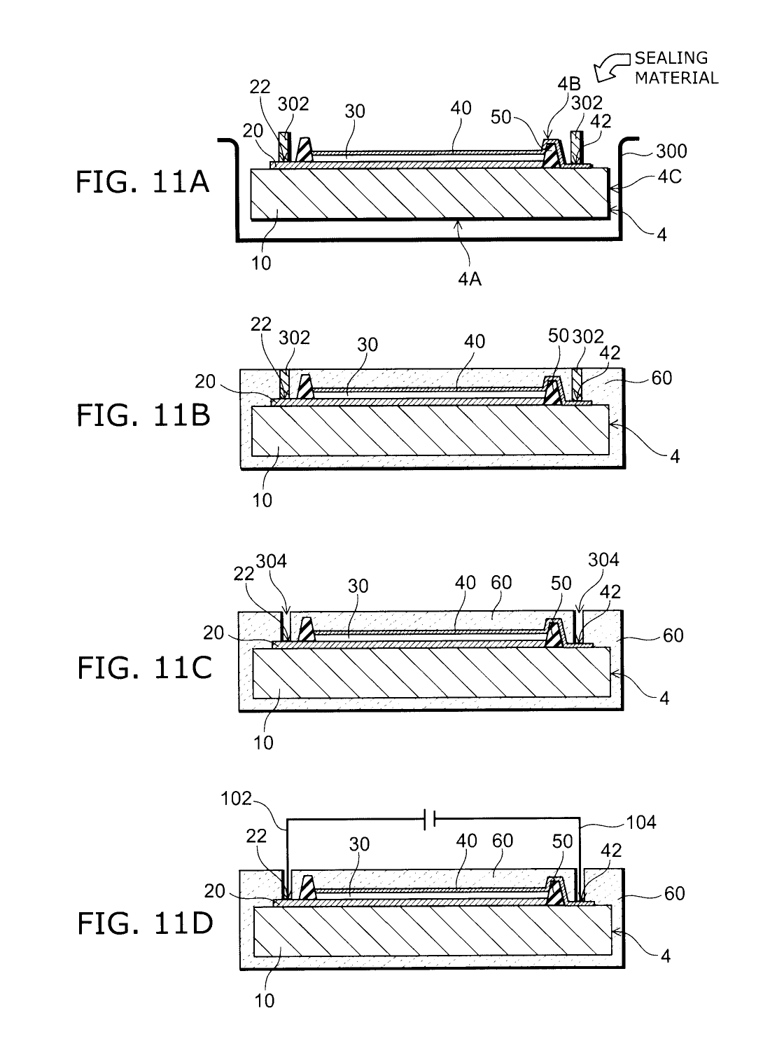

Next, the method for manufacturing the light-emitting device sealing structure according to this embodiment will be described with reference to FIGS. 10A to 11D. FIGS. 10A to 10D are schematic process cross-sectional views showing one example of the method for manufacturing the light-emitting device sealing structure 2. In this specific example, the organic EL element was used for the light-emitting device 4.

First, as shown in FIG. 10A, the light-emitting device 4 (for example, the organic EL element described above for the specific example 1) is fabricated. For the method for fabricating the organic EL element, for example, the method disclosed in Patent document 1 can be exemplified. Next, in a mold 300, the light-emitting device 4 is placed. Then, a material of the sealing layer 60 is flowed into the mold 300. The material of the sealing layer 60 includes, for example, a thermoplastic material softened by heat (such as “thermoplastic siloxane-based inorganic-organic hybrid material” described above for the specific example 1).

Next, as shown in FIG. 10B, the processed body is gradually cooled to solidify the sealing layer 60. Then, the processed body is taken out.

Next, as shown in FIG. 10C, portions of the power supply part 22 and the power supply part 42 on the sealing layer 60 are removed. The removal method includes, for example, a local melting process by laser. Then, as shown in FIG. 10D, the electrode lead wires 102 and 104 are attached to the power supply part 22 and the power supply part 42.

Thereby, the light-emitting device sealing structure 2 according to the specific example 1 (FIG. 1) is fabricated.

Next, another example of the method for manufacturing the light-emitting device sealing structure 2 will be described with reference to FIGS. 11A to 11D. FIGS. 11A to 11D are schematic process cross-sectional views showing the another example of the method for manufacturing the light-emitting device sealing structure 2. In this specific example, the organic EL element was used for the light-emitting device 4.

First, as shown in FIG. 11A, the light-emitting device 4 (for example, the organic EL element described above for the specific example 1) is fabricated. For the method for fabricating the organic EL element, for example, the method disclosed in Patent document 1 can be exemplified. Next, on the power supply part 22 and the power supply part 42 of the sealing layer 60, mask materials 302 are provided.

Next, in the mold 300, the light-emitting device 4 is placed. Then, the material of the sealing layer 60 is flowed into the mold 300. The material of the sealing layer 60 includes, for example, a thermoplastic material softened by heat (such as “thermoplastic siloxane-based inorganic-organic hybrid material” described above for the specific example 1).

Next, as shown in FIG. 11B, the processed body is gradually cooled to solidify the sealing layer 60. Then, the processed body is taken out. Then as shown in FIG. 11C, the mask materials 302 are removed. As a result, spaces 304 are generated

Then, as shown in FIG. 11D, the electrode lead wires 102 and 104 are attached to the power supply part 22 and the power supply part 42.

Thereby, the light-emitting device sealing structure 2 according to the specific example 1 (FIG. 1) is fabricated.

Moreover, although not shown, in the above process for FIG. 10C, only the portion of the vicinity of the electrode lead wires 102 and 104 of the sealing layer 60 may be locally processed and removed, and in the above process for FIG. 10D, the electrode lead wires 102 and 104 may be attached to the removed portion, and thereby, the light-emitting device sealing structure 2 according to the specific example 2 (FIG. 5) can be obtained. Alternatively, in the above process for the FIG. 10A, the electrode lead wires 102 and 104 may be preliminarily attached to the light-emitting device 4 and then the material of the sealing layer 60 may be flowed, and the sealing layer 60 may be cooled and solidified, and thereby, the light-emitting device sealing structure 2 according to the specific example 2 (FIG. 5) can be obtained, too.

Moreover, in the above process for FIG. 10C, the portion of the output region 90 of the sealing layer 60 or additionally part of the peripheral portion may be processed and removed, and thereby, the light-emitting device sealing structure 2 according to the specific example 3 (FIGS. 6A and 6B) can be obtained. Alternatively, in the above process for FIG. 11A, the portion of the output region 90 of the sealing layer 60 or additionally part of the peripheral portion may be provided with the mask material 302, and the same processes as the FIGS. 11B to 11D may be carried out and thereby the light-emitting device sealing structure 2 according to the specific example 3 (FIGS. 6A and 6B) can be obtained, too.

As described above, according to this embodiment, the thermoplastic material excellent in easiness of processing can be used for the sealing layer 60, and therefore, the sealing process is easier than a dry process or the like in which a vacuum apparatus is used. Therefore, the relatively inexpensive light-emitting device sealing structure is provided. Moreover, because the light-emitting device 4 is covered with the sealing layer 60, the light-emitting device sealing structure excellent in moisture-proof property is provided. Furthermore, by appropriately selecting the material of the sealing layer 60, the moisture-proof property is further improved.

The case where the organic EL element is used for the light-emitting device 4 has been described mainly in the above, but other light-emitting devices can also be used.

As described above, the embodiments of the invention has been described with reference to the specific examples. However, the invention is not limited to these specific examples. That is, the specific examples appropriately modified by those skilled in the art are also included in the scope of the invention as long as including the characteristics of the invention. For example, each of components of each of the above specific examples and its disposition, material, condition, shape, size, and so forth are not limited to the exemplified ones but can be appropriately modified.

Moreover, the components of each of the above embodiments can be combined in the technically possible range, and the combinations thereof are also included in the scope of the invention as long as including the characteristics of the invention.

1. A light-emitting device sealing structure, comprising:
a light-emitting device including, a front surface having an output region from which light is output and a peripheral portion provided in a surrounding area thereof, a back surface opposite to the front surface, and a peripheral side surface between the front surface and the back surface; and
a sealing layer covering the light-emitting device from the approximately entire back surface through the entire peripheral side surface to at least the peripheral portion of the front surface of the light-emitting device.

2. The structure according to claim 1, wherein the light-emitting device has a light-emitting element emitting light and a power supply part configured to supply a power to the light-emitting element, and the power supply part is not covered with the sealing layer.

3. The structure according to claim 1, wherein the output region is not covered with the sealing layer.

4. The structure according to claim 1, wherein an entirety of the front surface, the back surface and the peripheral side surface is covered with the sealing layer.

5. The structure according to claim 1, further comprising an inorganic layer that is stacked on a surface of the sealing layer and that is made of a material including an inorganic compound as a main component.

6. The structure according to claim 5, wherein the inorganic layer is provided only over the back surface.

7. The structure according to claim 1, further comprising a stress-relaxing layer that is provided between the light-emitting device and the sealing layer and that relaxes a stress generated between the light-emitting device and the sealing layer.

8. The structure according to claim 1, further comprising an adhesion layer that is provided between the light-emitting device and the sealing layer and that adheres the light-emitting device to the sealing layer adhere tightly.

9. The structure according to claim 1, further comprising:
a stress-relaxing layer that is provided between the light-emitting device and the sealing layer and that relaxes a stress generated between the light-emitting device and the sealing layer; and
an adhesion layer adhering the light-emitting device to the sealing layer adhere tightly.

10. The structure according to claim 1, wherein the sealing layer is made of a thermoplastic material.

11. The structure according to claim 1, wherein the sealing layer is made of a thermoplastic material having a siloxane bond and an organic functional group.

12. The structure according to claim 1, wherein the sealing layer is made of a material including a material selected from, organic-inorganic hybrid low-melting-point glass that is obtained by heating and reacting alkylchlorosilane and phosphorous acid and that has a composition of xR₂SiCl₂.H₃PO₃ (x=0.1 to 3) (where, R is methyl group or ethyl group), and organic-inorganic hybrid low-melting-point glass that is obtained by heating and reacting alkylchlorosilane and phosphorous acid and metal chloride and that has a composition of xR₂SiCl₂.2H₃PO₃.2MCl₂ (x=0.1 to 2) (where, M is bivalent metal of Sn, Zn, or Ge. R is methyl group or ethyl group).

13. The structure according to claim 1, wherein the sealing layer shields an ultraviolet ray.

14. The structure according to claim 1, wherein the light-emitting device has an organic EL layer.

15. A method for manufacturing a light-emitting device sealing structure, comprising:
flowing a material of a sealing layer made of a thermoplastic material softened thermally into a mold after placing a light-emitting device having a light-emitting element and a power supply part configured to supply a power to the light-emitting element in the mold;
cooling the processed body gradually to solidify the sealing layer;
removing a portion of the power supply part on the sealing layer by a laser melting process; and
attaching an electrode lead wire to the power supply part.

16. The method according to claim 15, wherein the light-emitting device has an output region from which light is output, and the method further comprises removing a portion of the output region on the sealing layer by a laser melting process, after said attaching the electrode lead wire.

17. The method according to claim 15, wherein the thermoplastic material has a siloxane bond and an organic functional group.

18. A method for manufacturing a light-emitting device sealing structure, comprising:
providing a mask material on a power supply part of a light-emitting device having a light-emitting element and the power supply part configured to supply a power to the light-emitting element;
flowing a material of a sealing layer made of a thermoplastic material softened thermally into a mold after placing the light-emitting device provided with the mask material in the mold;
cooling the processed body gradually to solidify the sealing layer;
removing the mask material; and
attaching an electrode lead wire to the power supply part.

19. The method according to claim 18, wherein the thermoplastic material has a siloxane bond and an organic functional group.

20. A method for manufacturing a light-emitting device sealing structure, comprising:
attaching an electrode lead wire to a power supply part of a light-emitting device having a light-emitting element and the power supply part configured to supply a power to the light-emitting element;
flowing a material of a sealing layer made of a thermoplastic material softened thermally into a mold after placing the light-emitting device in the mold; and
cooling the processed body gradually to solidify the sealing layer.
